(19) United States
(12) Patent Application Publication
(10) Pub. No.: US 2009/0246460 A1
(43) Pub. Date: Oct. 1, 2009

(54) Structure And Method For Forming Crystalline Material On An Amorphous Structure

(76) Inventors: Hans Cho, Palo alto, CA (US); Theodore I. Kamins, Palo Alto, CA (US); Nathaniel Quitoriano, Pacifica, CA (US)

Correspondence Address: HEWLETT PACKARD COMPANY, P O BOX 272400, 3404 E. HARMONY ROAD, INTELLECTUAL PROPERTY ADMINISTRATION, FORT COLLINS, CO, 80527-2400, US

(21) Appl. No.: 12/243,834

(22) Filed: Oct. 1, 2008

Related U.S. Application Data
(60) Provisional application No. 61/039,484, filed on Mar. 26, 2008.

(51) Int. Cl. H01L 21/20; B32B 9/04; B32B 3/10

(52) U.S. Cl. 428/138; 428/446; 428/698; 428/702; 428/192; 428/201; 438/478; 257/E21.09

(57) ABSTRACT

A structure includes a first amorphous layer and a second amorphous layer established on the first amorphous layer such that at least an edge of the first amorphous layer or the second amorphous having a predetermined geometry is exposed. A material having a controlled crystal orientation is selectively formed adjacent the exposed edge of the first amorphous layer or the second amorphous having the predetermined geometry.

### CROSS-REFERENCE TO RELATED APPLICATION

The present application claims priority from provisional application Ser. No. 61/039,484, filed Mar. 26, 2008, the contents of which are incorporated herein by reference in their entirety.

### BACKGROUND

The present disclosure relates generally to structures and methods for forming crystalline materials on amorphous structures.

Semiconductor materials may be suitable for use as a template for many devices, including various electronic and optical devices. In many applications (including, but not limited to, three-dimensional integration of multiple layers), it may be desirable that such materials have a uniform crystal orientation and be established on amorphous substrates. Deposition on an unpatterned amorphous structure generally results in a layer with a variety of different crystal orientations. Obtaining a uniform crystal orientation may involve recrystallization of a deposited precursor film via heat lamp or laser annealing, or bonding of a crystal film that has been detached from another bulk crystal mass. Such processes may result in film defects/damage and/or may be difficult to apply to multiple layers. For example, exposing the elevated layers in three-dimensionally integrated circuits to high process temperatures (e.g., those used in heat lamp or laser annealing recrystallization) may deleteriously affect the circuits and devices in underlying layers.

### BRIEF DESCRIPTION OF THE DRAWINGS

Features and advantages of embodiments of the present disclosure will become apparent by reference to the following detailed description and drawings, in which like reference numerals correspond to the same or similar, though perhaps not identical, components. For the sake of brevity, reference numerals having a previously described function may or may not be described in connection with subsequent drawings in which they appear.

FIG. 1 is a flow diagram depicting an embodiment of the method for forming crystalline material on an amorphous structure;

FIGS. 2A through 2G together depict a semi-schematic cross-sectional flow diagram of embodiments of a method of forming structures in which a substantially flat surface of a first amorphous material and an edge of a second amorphous layer are exposed, and a crystalline material is formed adjacent to an interface of the first and second amorphous layers;

FIGS. 3A through 3E together depict a semi-schematic cross-sectional flow diagram of an embodiment of a method of forming a structure in which an edge of a first amorphous layer is exposed, and a crystalline material is formed adjacent to the exposed edge;

FIG. 4 is a semi-schematic perspective view of an embodiment of a structure in which an exposed edge of a first amorphous layer bounds a shape with multiple angles adjacent to which crystalline materials are formed; and

FIG. 5 is a semi-schematic perspective view of an embodiment of a structure in which an exposed edge of a first amorphous layer bounds a shape with a single angle adjacent to which a crystalline material is formed.

### DETAILED DESCRIPTION

Embodiments of the structure and method disclosed herein advantageously have crystalline materials formed on amorphous materials. The methods promote the arrangement of the crystalline materials at predetermined locations in the structure. The methods advantageously enable one to control the orientation of the crystalline materials by controlling the geometry of the amorphous layer at which crystalline materials nucleate. Furthermore, the methods disclosed herein are advantageously performed at temperatures that are low enough (e.g., equal to or less than 600° C.) to substantially prevent undesirable damage to lower layers during manufacturing of elevated layers of a multi-layered three-dimensionally integrated circuit or to substantially prevent undesirable damage to an underlying substrate during manufacture of a single layer device.

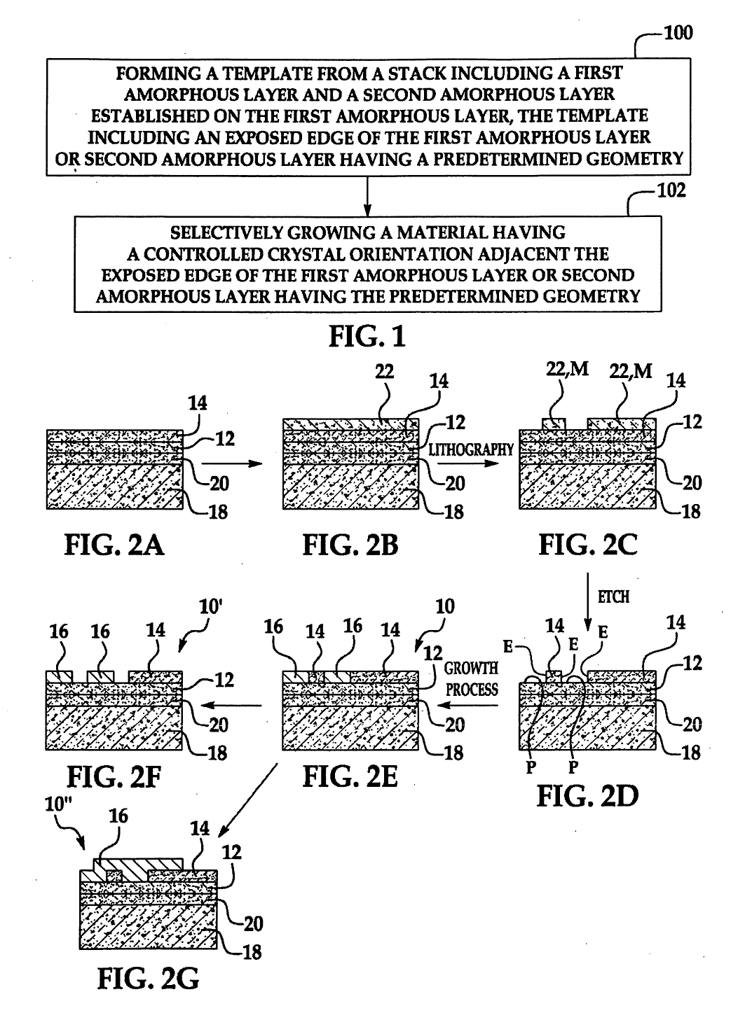

FIG. 1 illustrates an embodiment of the method disclosed herein. Generally, the method includes forming a template from a stack including a first amorphous layer and a second amorphous layer established on the first amorphous layer, as shown at reference numeral 100. The template includes an exposed edge of the first amorphous layer or the second amorphous layer having a predetermined geometry. The method further includes selectively growing a material having a controlled crystal orientation adjacent the exposed edge of the first amorphous layer or the second amorphous layer having the predetermined geometry, as shown at reference numeral 102. The controlled crystal orientation of the material may be uniform, in part because such materials are formed adjacent patterned surfaces having a desirable geometry that enhances the orientation. It is to be understood that the various embodiments of the method and the resulting structures are discussed further in reference to FIGS. 2A-2G, 3A-3E, 4 and 5.

Each of the structures 10, 10′, 10″, 10′″, 10″″, 10′″″ (see FIGS. 2E, 2F, 2G, 3E, 4 and 5) includes at least a first amorphous layer 12, a second amorphous layer 14 established on the first amorphous layer 12 such that at least a portion P having a predetermined geometry is exposed. A material 16 (also referred to herein as crystalline material 16) having a controlled crystal orientation is formed adjacent the exposed portion P. In some instances, the portion P is an edge E, which is discussed further hereinbelow.

The materials for the amorphous layers 12, 14 and the crystalline material 16 are selected such that the crystalline material 16 preferentially nucleates on one of the layers 12, 14. Non-limiting examples of the amorphous layers 12, 14 include silicon nitride, aluminum oxide, aluminum nitride, titanium oxide, hafnium oxide, and silicon dioxide; and non-limiting examples of the crystalline material 16 include silicon, germanium, carbon (e.g., graphitic carbon), III-V semiconductors, II-VI semiconductors, magnetic materials, metals (e.g., Al, Cu, Au, Fe, Co, or alloys thereof), or combinations thereof. As such, the respective amorphous layers 12, 14 that are used will depend, at least in part, on the crystalline material 16. In a non-limiting example, the first amorphous layer 12 is silicon nitride, the second amorphous layer 14 is silicon dioxide, and the crystalline material 16 is germanium (which preferentially nucleates on silicon nitride rather than on silicon dioxide).

FIGS. 2A through 2G depict embodiments of the method for forming various embodiments of the structure 10 (shown in FIG. 2E), 10′ (shown in FIG. 2F) and 10″ (shown in FIG. 2G) including the crystalline material 16 preferentially formed adjacent a portion P of the first amorphous layer 12 having a predetermined geometry and/or an edge E of the second amorphous layer having a predetermined geometry. As shown in FIG. 2A, this embodiment includes the first and second amorphous layers 12, 14 deposited on a substrate 18 which includes an additional amorphous layer 20 established thereon. In a non-limiting example, the substrate 18 is made of silicon, and a surface thereof is oxidized to form amorphous layer 20. In some instances, the substrate 18 is formed of an insulating and/or amorphous material (e.g., glass), and in other instances, the substrate 18 is formed of a semiconducting (e.g., silicon) or a conducting material (e.g., metal). Embodiments of the structures 10, 10′, 10″ including insulating or amorphous substrates 18 may be particularly suitable for thin film transistors in LCD displays.

Generally, in the embodiments disclosed herein, if both the first and second amorphous layers 12, 14 are etched through, the substrate 18 upon which they are established is formed of an amorphous material or includes an amorphous layer 20 thereon. If the first amorphous layer 12 remains un-etched (i.e., is not etched through), the substrate 18 may be formed of any material, including conducting, semiconducting, or insulating materials. Furthermore, in embodiments where the first amorphous layer 12 is un-etched, it is to be understood that the amorphous layer 20 may or may not be used.

It is to be understood that in instances in which it is undesirable to etch underlying layers (e.g., first amorphous layer 12 or additional amorphous layer 20), selective etching processes may be used in which the underlying layer(s) 12, 20 function as an etch stop when etching the layer(s) 12, 14 established thereon.

As shown in FIG. 2A, the first amorphous layer 12 is deposited on the additional amorphous layer 20, and the second amorphous layer 14 is formed (e.g., deposited, grown, etc.) on the first amorphous layer 12. Such layers 12, 14, 20 may be formed via any suitable technique, including, but not limited to low-ressure chemical vapor deposition (LPCVD), plasma enhanced chemical vapor deposition (PECVD), atmospheric pressure chemical vapor deposition (APCVD), thermal oxidation, spin on techniques, or any other suitable chemical or physical vapor deposition techniques. In a non-limiting example, both the first and second amorphous layers 12, 14 are deposited at temperatures below about 500° C. using plasma-enhanced chemical vapor deposition. After the layers 12, 14 are deposited they may be subjected to annealing at gradually increasing temperatures. It is believed that the annealing process removes the hydrogen content that may be imparted during the deposition. Hydrogen content removal may be particularly suitable after low temperature deposition processes are used.

In this embodiment, the second amorphous layer 14 is patterned and etched to expose one or more portions P of the first amorphous layer 12 and one or more edges E of the second amorphous layer 14. As shown in FIGS. 2B and 2C, a resist 22 is established on the second amorphous layer 14, and a pattern is formed therein via a suitable lithography technique (e.g., electron beam lithography, photolithography, or nanoimprint lithography). It is to be understood that the lithography technique selected depends, at least in part, on the size (micro-scale, nano-scale, etc.) and shape of the pattern. The pattern may have any suitable shape and/or size, such as, for example, straight lines or one or more shapes. As a non-limiting example, the pattern includes multiple separate shapes (e.g., squares) that are about 1 to 2 microns apart and have individual areas that range from about 100 nm² to about 20,000 nm².

The exposed regions of the resist 22 are removed via a developer solution, thereby forming a mask M with opening(s) defined therein (see FIG. 2C). The second amorphous layer 14 may then be etched through the opening(s) of the mask M using a buffered oxide etch (e.g., ammonium hydroxide/hydrofluoric acid solution) or a dry-etching technique (e.g., plasma etching or reactive ion etching). The removal of the exposed portion(s) of the second amorphous layer 14 exposes substantially flat surface(s) (i.e., portions P, shown in FIG. 2D) of the first amorphous layer 12 and edges E of the second amorphous layer 14. The mask M may then be removed via a photomask stripper or an oxygen plasma. The photomask stripper may contain an organic solvent (e.g., acetone) that removes the mask M without deleteriously affecting the other solid-state structures.

In this embodiment, the substantially flat surface(s) of the exposed portions P of the first amorphous layer 12 and/or the edge E of the second amorphous layer 14 has the predetermined geometry that acts as a template for growth of the crystalline material 16.

In previous applications, flat geometry resulted in crystalline material growing anywhere on the exposed surface and having an out-of-plane orientation that is not uniform and an in-plane orientation that is not uniform. The out-of-plane orientation may not be random, but it is also generally not uniform, rather, the amount and type of orientation depends, at least in part, on the materials and growth conditions utilized.

However, in the embodiments disclosed herein, the exposed portion(s) P are small (i.e., less than the surface diffusion length of the atoms deposited to form the crystalline material 16), and thus the deposited atoms are able to move throughout the portion P without forming a nucleus with other deposited atoms on the surface away from the edges E of the second amorphous layer 14. If the interface of the first and second amorphous layers 12, 14 that is exposed at the edges E adjacent the portion P is lower in energy than the areas of the portion P away from the edges E, nucleation (i.e., initiation of crystal growth) will preferentially occur adjacent the edges E, and the orientation of the growing crystalline material 16 may be substantially determined by the geometry of the edges E.

It is to be understood that the edge E may be a linear edge (i.e., a straight line) or an edge that encloses a pattern (e.g., the sides of a square).

In another embodiment, the substantially flat surfaces of the portion(s) P are intentionally damaged by exposing the surface to ion etching/bombardment or ion implantation. It is believed that such processes generate loose chemical bonds, thereby increasing the probability of selective nucleation of the crystalline material 16 at that portion P.

The structure shown in FIG. 2D (e.g., the exposed portion(s) P of the first amorphous layer 12 and the remaining second amorphous layer 14, including edges E) is exposed to a process that initiates nucleation of the crystalline material 16. Chemical vapor deposition, molecular beam epitaxy, or liquid phase epitaxy may be used to grow the crystalline material 16. Precursors to the desirable crystalline material 16 (e.g., germane may be used when forming crystalline germanium) may be used in the growth process, and may be delivered via a suitable carrier gas (e.g., H₂). Generally, the growth process conditions include a temperature equal to or less than 600° C. The growth process may also include an initial high growth rate step, which encourages nucleation, followed by continued growth of the previously formed nuclei (rather than formation of additional nuclei). Continued growth may also be performed using an additional process gas (e.g., HCl) to inhibit random nucleation. When chemical vapor deposition is used, the initial high growth rate step may be performed at high pressure and partial pressure (e.g., 90 Torr, 1 slm H₂ and 2 sccm of GeH₄), and the continued growth step may be performed at a reduced pressure and partial pressure (e.g., 10 Torr, 3 slm H₂ and 2 sccm of GeH₄). In one embodiment, nucleation is initiated using chemical vapor deposition or molecular beam epitaxy, and growth is continued using liquid phase epitaxy.

It is to be understood that growth may be carried out at a temperature equal to or less than 500° C., or at a temperature equal to or less than 400° C. (which is compatible with a metallization system, i.e., previously fabricated underlying layers of metallized devices and circuitry).

In the embodiment of the structure 10 shown in FIG. 2E, the crystalline material 16 preferentially grows on the exposed portion(s) P of the first amorphous layer 12 adjacent the edge E instead of on the surface of the second amorphous layer 14. In this embodiment, growth may be continued until the crystalline material 16 substantially fills the portion P.

After the crystalline material 16 grows, some or all of the second amorphous layer 14 may be removed via a selective etching process, as illustrated by the spaces between the crystalline materials 16 of the structure 10′ shown in FIG. 2F.

In the embodiment of the structure 10″ shown in FIG. 2G, growth of the crystalline material 16 is continued such that it extends laterally across at least a portion of the second amorphous layer 14 that is adjacent to the portions P and edges E.

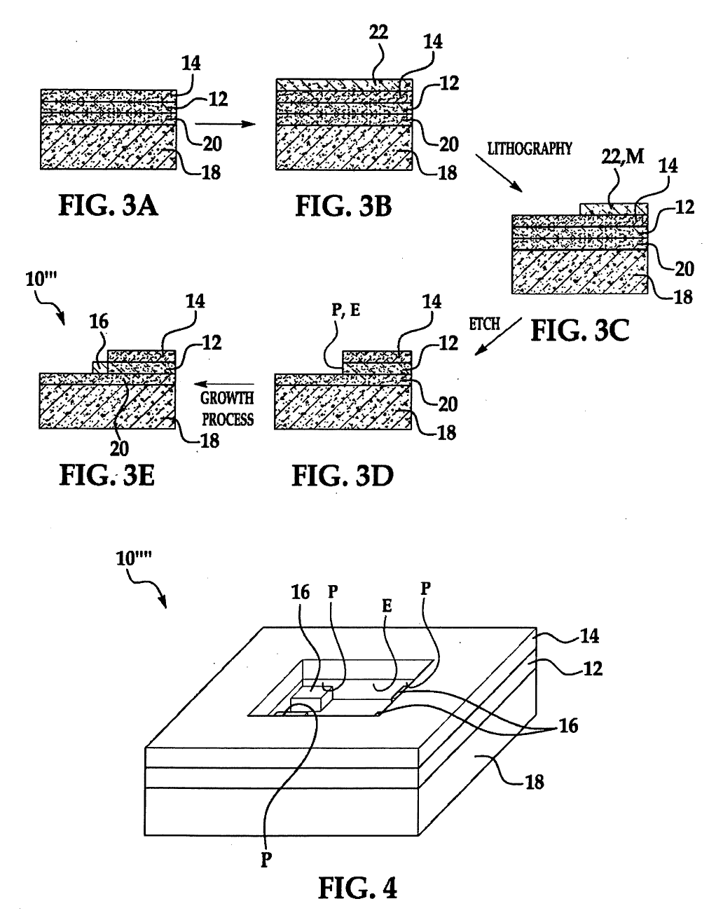

FIGS. 3A through 3E depict still another embodiment of the method for forming another embodiment 10′″ of the structure (shown in FIG. 3E). Like the other embodiments of the structure 10, 10′, 10″, the structure 10′″ shown in FIG. 3E includes the crystalline material 16 preferentially formed adjacent a portion P of the first amorphous layer 12 having a predetermined geometry.

As shown in FIG. 3A, the first amorphous layer 12 is deposited on the additional amorphous layer 20 of the substrate 18, and the second amorphous layer 14 is deposited on the first amorphous layer 12. In this embodiment, the stack (including the first and second amorphous layers 12, 14) is patterned and etched to expose one or more portions P of the first amorphous layer 12. As shown in FIGS. 3B and 3C, a resist 22 is established on the second amorphous layer 14, and a pattern is formed therein via a suitable lithography technique. The exposed regions of the resist 22 are removed via a developer solution, thereby forming a mask M having an exposed edge that is positioned such that at least some portion of the second amorphous layer 14 remains covered by the mask M, and another portion of the second amorphous layer 14 becomes exposed (see FIG. 3C).

In this embodiment, the first and second amorphous layers 12, 14 are then etched at region(s) where the mask M has been removed. When the second amorphous layer 14 is an oxide, it may be etched using a buffered oxide etch or a dry-etching process, and when the first amorphous layer 12 is a nitride, it may be etched using a dry-etching process or phosphoric acid at a temperature ranging from about 140° C. to about 180° C., which etches the nitride at a rate of several tens of angstroms per minute while leaving the oxide substantially un-etched.

It is to be understood that the mask M may be removed (e.g., using the previously described photomask stripper or oxygen plasma) after the second amorphous layer 14 has been removed and before the first amorphous layer 12 is removed, or after both layers 12, 14 have been removed. When the mask M is removed prior to the first amorphous layer 12, it is to be understood that the second amorphous layer 14 acts as a mask for removal of the first amorphous layer 12.

It is to be further understood that when the first amorphous layer 12 is etched through (see FIGS. 3E, 4 and 5), the portion P is an edge E of the first amorphous layer 12 that is exposed and forms a band that equals the perimeter of the pattern defined in the resist 22. In some instances (and as previously mentioned in reference to the edge E in FIG. 2D), the edge E may be substantially straight and extend a relatively long distance when compared to any other dimensions, and in other instances, the edge E may include the sides of a shape (or other pattern) (see FIG. 4).

FIG. 3D depicts the structure after both of the amorphous layers 12, 14 have been etched. The etching process results in the exposure of portion P, which, in this embodiment, is an edge E of the first amorphous layer 12. This edge E is the predetermined geometry that acts as a template for growth of the crystalline material 16. The orientation of the growing crystalline material 16 is substantially determined by the geometry of the edge E. Furthermore, the number of crystalline material 16 nuclei formed on the edge E depends, at least in part, on the area and shape of the pattern bounded by the edge E and/or the length of the edge E exposed to the growth process. As such, in this embodiment, by controlling one or more of the shape of the pattern, the geometry of the edge E, the deposition conditions, and other factors, the crystal orientation of the crystalline material 16 may also be controlled.

The structure shown in FIG. 3D is exposed to the selected growth process(es) (e.g., chemical vapor deposition, molecular beam epitaxy, or liquid phase epitaxy). As previously described, precursors to the desirable crystalline material 16 (e.g., germane may be used when forming crystalline germanium) may be used in the growth process, and may be delivered via a suitable carrier gas (e.g., H₂).

In the embodiment shown in FIG. 3E, the crystalline material 16 preferentially grows adjacent to the exposed portion(s) P of the first amorphous layer 12 instead of on the second amorphous layer 14 or on other areas of the additional amorphous layer 20.

Referring now to FIG. 4, still another embodiment of the structure 10″″ is depicted. This embodiment of the structure 10″″ is formed via the method discussed in reference to the FIG. 3 series, and illustrates that the patterning and etching results in the formation of one or more closed shapes (as opposed to a linear edge) with several angles bounded by edge E and defined in the amorphous layers 12, 14. A non-limiting example of the shape is a rectangle that is about 400 nm by about 100 nm (i.e., 4:1 length:width ratio).

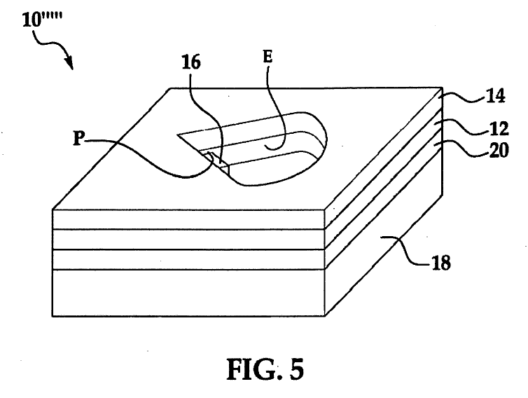

The substrate 18 in both FIGS. 4 and 5 (the latter of which is discussed further hereinbelow) are amorphous materials or include an amorphous layer 20, such as silicon dioxide, in part because the first amorphous layer 12 is etched through.

In this embodiment, the angles are elements of the predetermined geometry and constitute corner nucleation sites which act as templates onto which the crystalline material 16 grows. It is to be understood that the specific lattice structure of the growing crystalline material 16 is defined by the vertex angle. This may be due, at least in part, to the general energetic advantage of nucleating at a corner (angle) of the edge E as opposed to on a linear edge or a flat surface. For example, a crystalline material 16 nucleated at a corner patterned into an oxide (second amorphous layer 14)/nitride (first amorphous layer 12)/oxide) stack is expected to have the tendency towards a corresponding crystal geometry. For example, when germanium is formed and the angle is a right angle, such a crystal would have its [100] faces oriented parallel and/or normal to the walls adjacent the corners and the bottom oxide (e.g., layer 20) surface. It is to be understood that the angles may be obtuse angles, right angles, and/or acute angles. The shape and type of angle selected will depend, at least in part, on the desirable orientation for the resulting crystalline material 16.

FIG. 5 is similar to FIG. 4 in that the patterning and etching results in the formation of one or more shapes bound by edge E and defined in both of the amorphous layers 12, 14. In this embodiment however, the shape includes a single angle as the template, as opposed to the multiple angles shown in FIG. 4. The pattern of FIG. 5 is specifically shaped to include a single corner (e.g., a right angle, an obtuse angle, or an acute angle vertex), with the remainder of the perimeter being rounded and not containing angles. It is to be understood that nucleation may be confined to the single corner at certain growth conditions, thereby resulting in a single crystalline material 16 island for the pattern. For example, when the lateral diffusion length of germanium atoms is significantly greater than the maximum distance of any point on the pattern perimeter from the corner (as is the case at a higher temperature and lower partial pressure of reactant gases), such singular growth at the corner is enabled.

In any of the embodiments disclosed herein, an amorphous or polycrystalline semiconductor material (not shown) may be deposited over the nucleated crystalline material 16. The amorphous or polycrystalline semiconductor material may then be melted or otherwise heated (e.g., via laser irradiation or heat lamp irradiation) to induce crystallization or recrystallization, whereby the crystalline material 16 acts as an epitaxial seed for such crystallization or recrystallization.

Furthermore, in any of the embodiments disclosed herein, a semiconductor precursor in its liquid phase at a temperature below the melting point of the crystalline material 16 may be placed in contact with the crystalline material 16. In this embodiment, the crystalline material 16 seeds epitaxial crystal growth from the liquid semiconductor precursor.

Embodiments of the structure and method disclosed herein advantageously have crystalline materials 16 controllably formed on predetermined areas of an amorphous stack of materials. In some instances, the methods advantageously enable one to control the orientation of the crystalline materials 16 by controlling the geometry of the layer 12, 14 at which crystalline materials 16 nucleate.

While several embodiments have been described in detail, it will be apparent to those skilled in the art that the disclosed embodiments may be modified. Therefore, the foregoing description is to be considered exemplary rather than limiting.

What is claimed is:

1. A structure, comprising:
a first amorphous layer;
a second amorphous layer established on the first amorphous layer such that at least an edge of the first amorphous layer or the second amorphous layer having a predetermined geometry is exposed; and
a material having a controlled crystal orientation selectively formed adjacent the exposed edge of the first amorphous layer or the second amorphous layer having the predetermined geometry.

2. The structure as defined in claim 1 wherein the material having the controlled crystal orientation preferentially nucleates on the first amorphous layer or the second amorphous layer.

3. The structure as defined in claim 1 wherein the first and second amorphous layers are independently selected from silicon nitride, aluminum oxide, aluminum nitride, titanium oxide, hafnium oxide, and silicon dioxide, and wherein the first and second amorphous layers are selected such that the material having the controlled crystal orientation preferentially nucleates on the first amorphous layer or the second amorphous layer.

4. The structure as defined in claim 1, further comprising a substrate upon which the first and second amorphous layers are established.

5. The structure as defined in claim 1 wherein the predetermined geometry is a linear edge.

6. The structure as defined in claim 1 wherein at least one of the first or the second amorphous layers has defined therein at least one shape with a predetermined number of angles, and wherein the predetermined geometry includes the predetermined number of angles.

7. The structure as defined in claim 6 wherein the predetermined number of angles is one.

8. The structure as defined in claim 6 wherein one or more of the angles are right angles, obtuse angles, acute angles, or combinations thereof.

9. The structure as defined in claim 1 wherein the second amorphous layer is etched through to expose the first amorphous layer, and wherein the first amorphous layer remains un-etched.

10. The structure as defined in claim 1, further comprising an additional amorphous layer upon which the first amorphous layer is established, and wherein the first and second amorphous layers are etched through to expose the additional amorphous layer.

11. The structure as defined in claim 1 wherein the predetermined geometry defines the controlled crystal orientation.

12. The structure as defined in claim 1 wherein the material having a controlled crystal orientation is silicon, germanium, carbon, III-V semiconductors, II-VI semiconductors, a metal, or combinations thereof.

13. A method for forming crystalline material on an amorphous structure, the method comprising:
forming a template from a stack including a first amorphous layer and a second amorphous layer established on the first amorphous layer, the template including an exposed edge of the first amorphous layer or the second amorphous layer having a predetermined geometry; and
selectively growing a material having a controlled crystal orientation adjacent the exposed edge of the first amorphous layer or the second amorphous layer having the predetermined geometry.

14. The method as defined in claim 13 wherein selectively growing is accomplished via chemical vapor deposition, molecular beam epitaxy, or liquid phase epitaxy.

15. The method as defined in claim 14 wherein selectively growing is accomplished at a temperature less than or equal to 600° C.

16. The method as defined in claim 13 wherein forming the template includes:
patterning the stack; and
etching at least one of the layers in the stack, thereby exposing the edge of the first amorphous layer or the second amorphous layer having the predetermined geometry.

17. The method as defined in claim 16 wherein the second amorphous layer is etched through to expose a portion of the first amorphous layer, and wherein the method further comprises damaging a surface of the portion of the first amorphous layer to increase the probability of selectively growing on the portion of the first amorphous layer.

18. The method as defined in claim 17 wherein damaging is accomplished via reactive ion etching, ion bombardment, or ion implantation.

19. The method as defined in claim 13, further comprising:
forming the stack by depositing the first amorphous layer on a substrate and depositing the second amorphous layer on the first amorphous layer; and
annealing the first and second amorphous layers to remove hydrogen content imparted during deposition.

20. The method as defined in claim 13 wherein the predetermined geometry of the exposed edge is a linear edge or an angle vertex.

21. The method as defined in claim 13, further comprising controlling the crystal orientation by controlling the predetermined geometry.

22. The method as defined in claim 13, further comprising:
depositing an amorphous or polycrystalline semiconductor material on at least some of the material having the controlled crystal orientation; and
crystallizing or recrystallizing the deposited amorphous or polycrystalline semiconductor material using the material having the controlled crystal orientation as an epitaxial seed.

23. The method as defined in claim 13, further comprising exposing the material having the controlled crystal orientation to a liquid semiconductor precursor at a temperature below a melting point of the material having the controlled crystal orientation such that the material having the controlled crystal orientation seeds epitaxial crystal growth from the semiconductor liquid precursor.

24. The method as defined in claim 13 wherein selectively growing includes:
nucleating the crystalline material via chemical vapor deposition or molecular beam epitaxy; and
continuing growth of the previously grown crystalline material via liquid phase epitaxy.

25. The method as defined in claim 13 wherein selectively growing includes:
nucleating the crystalline material via chemical vapor deposition at an initial pressure and partial pressure; and
continuing growth of the previously grown crystalline material via chemical vapor deposition at a reduced pressure and partial pressure, or with an additional process gas to inhibit random nucleation.
